(19) United States
(12) Patent Application Publication
(10) Pub. No.: US 2019/0036482 A1
(43) Pub. Date: Jan. 31, 2019

(54) ADAPTIVE POWER MANAGEMENT OF ENERGY STORAGE FOR PV OUTPUT CONTROL

(71) Applicant: NEC Laboratories America, Inc., Princeton, NJ (US)

(72) Inventors: Chenrui Jin, Cupertino, CA (US); Babak Asghari, San Jose, CA (US); Ratnesh Sharma, Fremont, CA (US)

(21) Appl. No.: 16/037,381

(22) Filed: Jul. 17, 2018

Related U.S. Application Data
(60) Provisional application No. 62/537,982, filed on Jul. 28, 2017.
(60) Provisional application No. 62/608,592, filed on Dec. 21, 2017.

(51) Int. Cl. H02S 40/38; H02J 7/35; H01L 31/042; H02J 7/00

(52) U.S. Cl. CPC H02S 40/38; H02J 7/35; H02J 2007/0037; H02J 7/0081; H01L 31/042

(57) ABSTRACT

A computer-implemented method executed on a processor for outputting a smoothed photovoltaic (PV) power output from a battery of a power control system communicating with one or more microgrids is presented. The method includes curtailing an input signal received from a plurality of sensors, smoothing the input signal by employing a fuzzy logic based low pass filter having an adaptive window to generate a power reference command, applying a hard ramp rate limit to the power reference command, adjusting battery power output of the battery to satisfy battery constraints and a no-power-from-grid constraint, and distributing energy from the battery based on the adjusted battery power output.

### RELATED APPLICATION INFORMATION

This application claims priority to Provisional Application Nos. 62/537,982, filed on Jul. 28, 2017, and 62/608,592 filed on Dec. 21, 2017, incorporated herein by reference in their entirety.

### BACKGROUND

### Technical Field

The present invention relates to power management systems and, more particularly, to methods and systems for providing improved photovoltaic (PV) smoothing techniques

### Description of the Related Art

High levels of penetration of renewable energy resources, e.g., photovoltaic (PV), brings the grid great benefits while also poses several challenges on existing power grid infrastructure. One of the concerns comes from the short-term high-frequency fluctuations of PV generations during unpredictable sudden weather changes. For grid systems with limited response capacity, very fast fluctuation of PV generations can sometimes cause a complete power failure. It is thus necessary to find solutions to produce a smoother PV power output profile. Battery energy storage (BES), because of their fast ramping capabilities, become an essential part of those solutions. Meanwhile, it is important to design power control strategies to regulate battery charging/discharging to effectively mitigate PV output fluctuations. Because of the relatively high cost on battery purchase and maintenance, battery sizing and degradation should also be considered when designing power control strategies.

### SUMMARY

A computer-implemented method executed on a processor for outputting a smoothed photovoltaic (PV) power output from a battery of a power control system communicating with one or more microgrids is presented. The method includes curtailing an input signal received from a plurality of sensors, smoothing the input signal by employing a fuzzy logic based low pass filter having an adaptive window to generate a power reference command, applying a hard ramp rate limit to the power reference command, adjusting battery power output of the battery to satisfy battery constraints and a no-power-from-grid constraint, and distributing energy from the battery based on the adjusted battery power output.

A system for outputting a smoothed photovoltaic (PV) power output from a battery of a power control system communicating with one or more microgrids is also presented. The system includes a memory and a processor in communication with the memory, wherein the processor is configured to curtail an input signal received from a plurality of sensors, smooth the input signal by employing a fuzzy logic based low pass filter having an adaptive window to generate a power reference command, apply a hard ramp rate limit to the power reference command, adjust battery power output of the battery to satisfy battery constraints and a no-power-from-grid constraint, and distribute energy from the battery based on the adjusted battery power output.

A non-transitory computer-readable storage medium comprising a computer-readable program is presented for outputting a smoothed photovoltaic (PV) power output from a battery of a power control system communicating with one or more microgrids, wherein the computer-readable program when executed on a computer causes the computer to perform the steps of curtailing an input signal received from a plurality of sensors, smoothing the input signal by employing a fuzzy logic based low pass filter having an adaptive window to generate a power reference command, applying a hard ramp rate limit to the power reference command, adjusting battery power output of the battery to satisfy battery constraints and a no-power-from-grid constraint, and distributing energy from the battery based on the adjusted battery power output.

These and other features and advantages will become apparent from the following detailed description of illustrative embodiments thereof, which is to be read in connection with the accompanying drawings.

### BRIEF DESCRIPTION OF DRAWINGS

The disclosure will provide details in the following description of preferred embodiments with reference to the following figures wherein:

FIG. 1 is a block/flow diagram illustrating a four-layer photovoltaic (PV) control system, in accordance with embodiments of the present invention;

FIG. 2 is a block/flow diagram illustrating an integrated PV control system, in accordance with embodiments of the present invention;

FIG. 3 is a block/flow diagram illustrating energy storage system constraints, in accordance with embodiments of the present invention;

FIG. 4 is a block/flow diagram illustrating battery power dispatch, in accordance with embodiments of the present invention;

FIG. 5 is a block/flow diagram for determining minimal battery energy ratings, in accordance with embodiments of the present invention;

FIG. 6 is a block/flow diagram illustrating the features of the adaptive integrated PV control system, in accordance with embodiments of the present invention;

FIG. 7 is a block/flow diagram illustrating a fuzzy logic based adaptive power smoothing algorithm, in accordance with embodiments of the present invention;

FIG. 8 is block/flow diagram illustrating a method for achieving a smooth PV output profile, in accordance with embodiments of the present invention;

FIG. 9 is a block/flow diagram of an exemplary processing system, in accordance with embodiments of the present invention; and

FIG. 10 is a system configuration of PV generation integrated with a battery, in accordance with embodiments of the present invention.

### DETAILED DESCRIPTION OF PREFERRED EMBODIMENTS

High levels of penetration of renewable energy resources, e.g., photovoltaic (PV), brings grid benefits while also poses several challenges on existing power grid infrastructure. One of the concerns comes from the short-term high-frequency fluctuations of PV generations during unpredictable sudden weather changes, which has been reported at some central generation stations. A great effort has been put in the mitigation of the short-term fluctuation of PV power generation, which is generally referred to as “smoothing” or “ramp-rate” control. Another concern with PV integration into the grid is overvoltage when the PV generation exceeds a certain limit set by the connected distribution system. During high PV generation and low load periods, there is a possibility of reverse power flow, and consequently voltage rise, in a low-voltage (LV) feeder. The issue can be avoided by limiting the capacity of the PV units by employing inverters with active power curtailment. However, this may cause great waste of generated PV power. Using Energy Storage System (ESS), on the other hand, can limit active power injection into the grid while also saving excessive PV power for later dispatch.

In the exemplary embodiments of the present invention, methods and devices are presented for designing active power management systems to mitigate the impact of short-term variations of PV generation and to provide the grid with a smoother PV profile, while also prevents overvoltage by absorbing excessive PV power using ESS. The exemplary embodiments of the present invention are general enough to be applied to any PV generation profile and to achieve any target PV output profile with predetermined ramp rate and curtailment limit. The exemplary embodiments of the present invention also provide guidelines to choose or select optimal ESS size to reduce cost on infrastructure and operations.

In the exemplary embodiments of the present invention, an adaptive control system for a battery integrated with PV generation is designed to help solve the fluctuation in PV power generation and overvoltage. The exemplary embodiments of the present invention focuses on the design and implementation of a power control system (PCS), which deals with the power and energy dispatch of energy storage devices to simultaneously satisfy PV ramp rate limits and curtailment requirements. The core component of the exemplary embodiments of the present invention is a Fuzzy Logic based reference power scheduler for the battery, which mitigates variations in PV power output, while also limits battery throughput by monitoring the battery operation status, such as SOC, power limit, etc. The smoothed PV outputs will also be confined under the curtailment limit when the time is within the curtailment period.

In the exemplary embodiments of the present invention, the PCS has four layers. The first layer curtails the input raw PV generation. The second fuzzy-logic-based control layer smoothes the curtailed PV generation and makes sure the battery system constraints are satisfied. The third layer puts hard ramp rate limits on the smoothened PV profile to make sure the ramp rate constraint is strictly followed. The fourth layer fine-tunes the generated power reference to ensure the battery system constraints are satisfied and the battery only charges from PV, not from the grid. The power reference command is then send to the battery model to dispatch power to the grid and produce a controlled PV output profile.

It is to be understood that the present invention will be described in terms of a given illustrative architecture; however, other architectures, structures, substrate materials and process features and steps/blocks can be varied within the scope of the present invention. It should be noted that certain features cannot be shown in all figures for the sake of clarity. This is not intended to be interpreted as a limitation of any particular embodiment, or illustration, or scope of the claims.

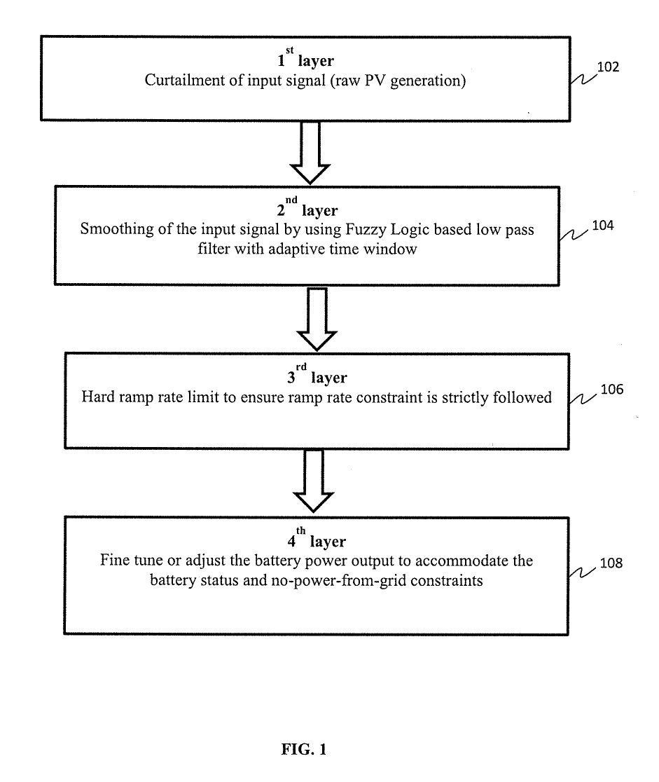

FIG. 1 is a block/flow diagram illustrating a four-layer photovoltaic (PV) control system, in accordance with embodiments of the present invention.

The power control system (PCS) can have four layers. The first layer 102 can read the original photovoltaic (PV) production. The second adaptive control layer 104 smoothes the curtailed PV generation with an adjustable time window and makes sure the battery system constraints are satisfied. The third layer 106 puts hard ramp rate limits on the smoothened PV profile to make sure the ramp rate constraint is strictly followed. The final layer 108 fine-tunes or adjusts the generated power reference to ensure the battery system constraints are satisfied and the battery only charges from PV, not from the grid. The power reference command is then sent to the battery to dispatch power to the grid and produce controlled PV output profile.

Therefore, in accordance with the exemplary embodiments, some or all of the following can be provided of the present invention:

An adaptive fuzzy logic based filter for PV smoothing is implemented where a PV smoothing algorithm effectively reduces PV output delay and battery throughput to achieve a balance between reducing PV ramp rate and limiting battery usage.

PV curtailment is combined or integrated with ramp rate control such that both objectives of PV active power curtailment and smoothening are achieved in real-time within one control system. Battery power and energy dispatch are scheduled considering limits from the PV generation and the power grid system.

A highly expandable control system is implemented to accommodate more constraints. The four layer control system does not need precise mathematical modeling or sophisticated computations, and can thus be easily updated along with the changes in energy storage components (e.g., the unit size, the operational concerns, etc.)

The battery status can be monitored throughout the whole control process. The battery status can be maintained within the battery's operational limits. Additionally, safe and sustainable operations of energy storage devices can be achieved.

Provide guidelines to choose or select optimal ESS size to reduce cost. By employing iterative methods, users can obtain the minimal battery size to satisfy the most important constraints, such as curtailment. Thus, cost on battery infrastructure and battery operations can be reduced, etc.

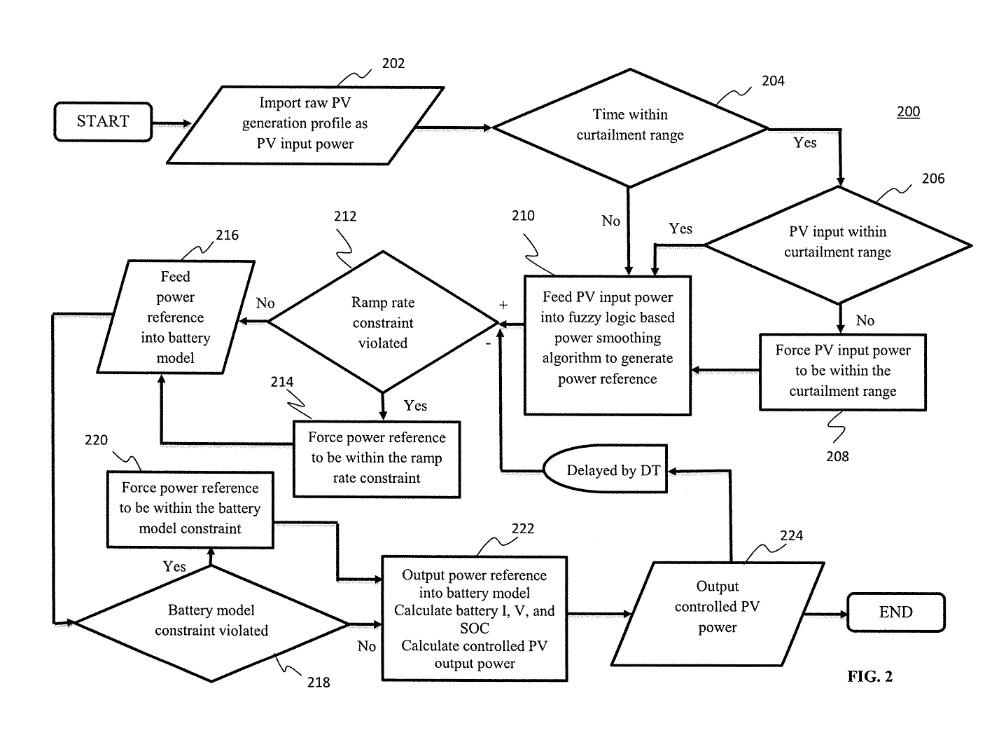

FIG. 2 is a block/flow diagram 200 illustrating an integrated PV control system, in accordance with embodiments of the present invention.

The input signal can be raw PV generation profiles 202. It is then determined whether a time is within a curtailment range 204. If YES, it is then determined whether the PV input is within the curtailment range 206. If NO, then force the PV input power to be within the curtailment range at block 208.

If the time is not within the curtailment range or if the PV input is within the curtailment range, then the process proceeds to block 210. At block 210, the method feeds the PV input power into the fuzzy logic based power smoothing algorithm to generate a power reference command.

At block 212, it is determined whether the ramp rate is violated. If YES, the power reference is forced to be within the ramp rate constraint 214. If NO, at block 216, the power reference is fed into the battery model.

At block 218, it is determined whether the battery model is violated. If YES, at block 220, the power reference is forced to be within the battery model constraint. If NO, then at block 222, the power reference is output into the battery model, the battery current, voltage, and SOC is calculated, and the controlled PV output power is calculated.

At block 224, the controlled PV power is output.

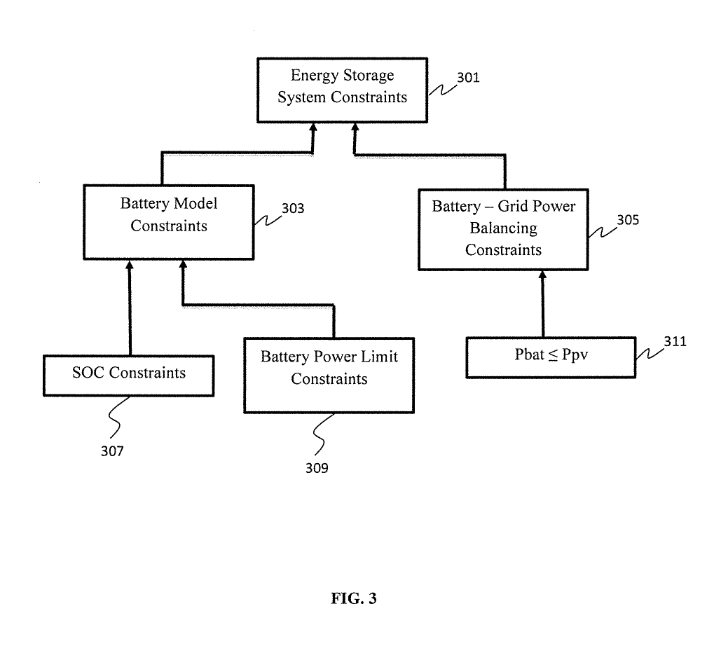

FIG. 3 is a block/flow diagram 300 illustrating energy storage system constraints, in accordance with embodiments of the present invention.

The energy storage system constraints 310 can include battery model constraints 303 and battery—grid power balancing constraints 305. The battery model constraints 303 can include at least state of charge (SOC) constraints 307 and battery power limit constraints 309. The battery—grid power balancing constraints 305 can include a power constraint 311 where Pbat≤Ppv.

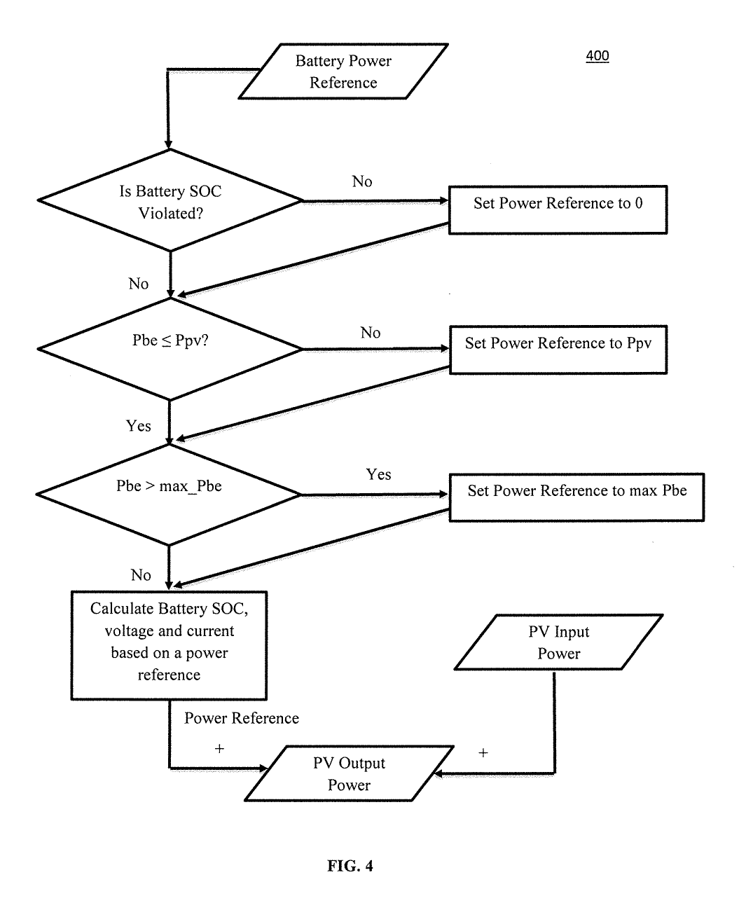

FIG. 4 is a block/flow diagram 400 illustrating battery power dispatch, in accordance with embodiments of the present invention.

The flow chart 400 depicts fine tuning battery power dispatch after the battery receives the power reference from the third layer 106.

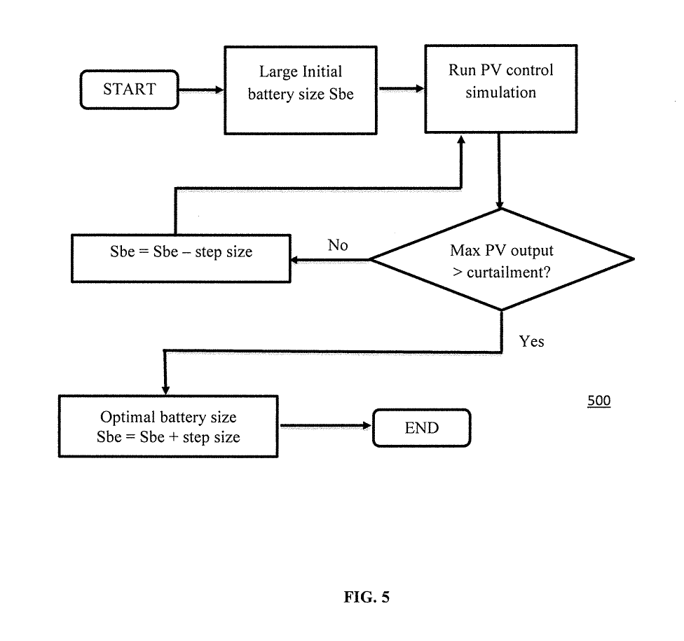

FIG. 5 is a block/flow diagram 500 for determining minimal battery energy ratings, in accordance with embodiments of the present invention.

When a user tries to find the minimal battery size that satisfies the PV curtailment requirement, the user can simulate PV power control iteratively to find the optimal battery size. The iterative process start with a large battery size and then reduces the size by a step value each iteration until the PV curtailment limit is violated.

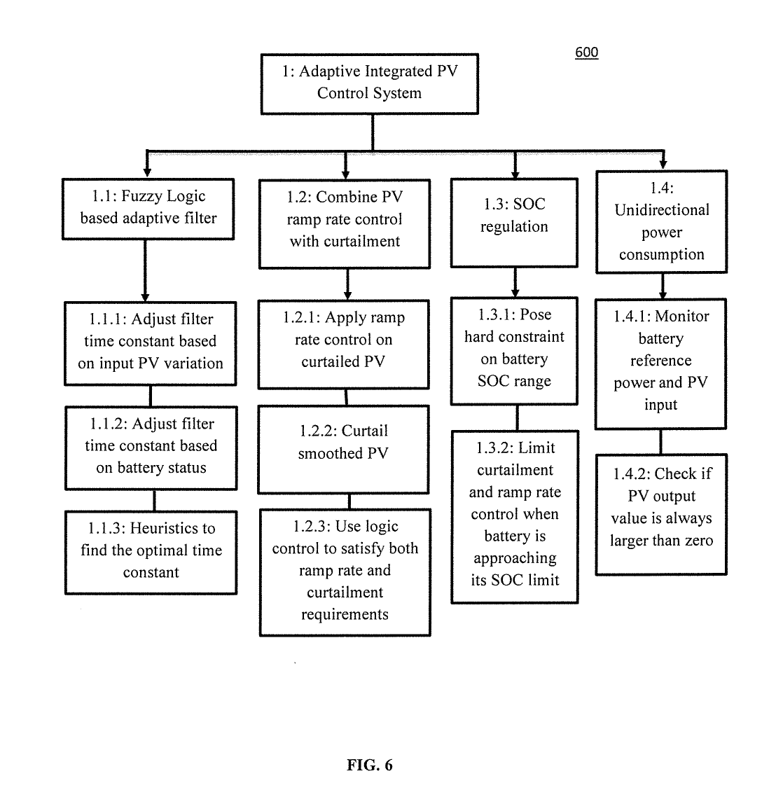

FIG. 6 is a block/flow diagram 600 illustrating the features of the adaptive integrated PV control system, in accordance with embodiments of the present

At block 1: Adaptive Integrated PV Control System

The Adaptive Integrated PV Control System can carry out multiple functions in PV output control, while it does not need complex mathematical modeling. So the system is a more general control method and is essentially rule-based, which makes it extendable to other operation constraints and scenarios.

At block 1.1: Fuzzy Logic Based Adaptive Filter

The Fuzzy Logic based adaptive filter for PV output smoothing can effectively reduce PV output delay and battery throughput, thus achieving a balance between reducing PV ramp rate and limiting battery usage. Other filtering approaches can introduce considerable time delay between the filtered signal and original signal, while the Fuzzy Logic based adaptive filter helps to minimize the time delay.

Power output smoothing time constant T1 controls the smoothness of the PV output and battery throughput, which is determined by the membership functions of control variables (e.g., input power variations, battery status, etc.). The rule base and membership function are developed and refined on the basis of expert knowledge, simulations, and experiments.

At block 1.2: Combine PV Ramp Rate Control with Curtailment

PV ramp rate control and curtailment are critical for efficient and safe PV integration into the grid. Instead of achieving those two objectives separately, the control system enables employs a solution to both issues with one control system.

At block 1.3: SOC Regulation

The operation of battery within SOC limits prescribed by the manufacturer prolongs battery's life. Further, operation of the battery within those constraints conserves the battery's capacity to participate in other applications, such as demand change control or ancillary service. The SOC limits are enforced in the Fuzzy Logic controller and battery power command refining process.

At block 1.4: Unidirectional Power Consumption

This block ensures the battery only charges from PV generation, not from the grid. This requirement is determined by the power system infrastructure. System inefficiencies and losses can be ignored.

P_{be}≤P_{PV} (1)

where P_{be} is the anticipated battery power and P_{PV} is the measured PV power during that instant. The anticipated power values have been calculated from the product of current command generated after hard limits and measured voltage value.

If the condition listed in (1) is violated, the power balancing block refines the reference values to meet the power balance requirements.

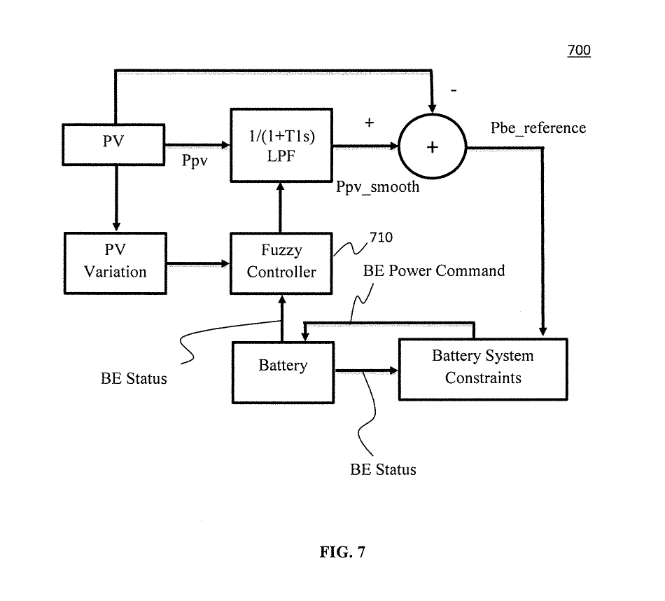

FIG. 7 is a block/flow diagram 700 illustrating a fuzzy logic based adaptive power smoothing algorithm, in accordance with embodiments of the present invention.

The PV power smoothing algorithm in the second layer of the power control system (PCS) is built with moving-average filter with adjustable time window. Unlike using pure ramp-rate control, which only acts when the fluctuation exceeds the maximum allowed ramp-rate limit, a moving-average filter smoothes the PV power curve by averaging PV power output within a predefined time window. The larger the time window is, the smoother the curve will be. However, a larger time window also introduces more power output offset from the original power input. Unnecessary battery charging or discharging occurs due to the power offset, which causes extra battery cycles with deep depth of discharge (DOD), leading to more battery degradation. Thus, it is necessary to build a mechanism that adjusts the time window so that when the PV input power is smooth, the time window is small, and when the PV power input is highly fluctuating, the time window increases to suppress the fluctuation.

The fuzzy-logic based controller 710 can adjust the time window employed in the moving average filter to reduce the power output offset effect when the PV production fluctuation is low, e.g., in clear weather, while still providing enough smoothing effect when the PV production is highly unstable, e.g., in cloudy or rainy weather.

Meanwhile, the algorithm also monitors the status of the battery to keep the SOC of the battery in a proper range to be ready for any discharging/charging command, i.e., to avoid energy depletion or overcharge. The proposed smoothing algorithm is shown in FIG. 7, where T1 is a time window employed in the low-pass filter (LPF), e.g., the moving-average filter.

The fuzzy-logic based controller 710 can take two input variables: the variation in PV power production and the SOC of the battery SoC(t) in real-time.

The variation in PV power production is calculated by the following equation:

dP(t)=|mean(Ppv(t−T), Ppv(t))−P(t)|/RR (5);

where mean(Ppv(t−T), Ppv(t)) calculates the time average value of Ppv in the time period t to t+T, where T is a predetermined time range; RR is the ramp-rate limit for that time range. dP(t) is an indicator of PV fluctuation at time t.

The output of the controller 710 is the adjusted time window dT(t), taking a value between 0 to 1.

The real-time time window for the moving-average algorithm is calculated as T1(t)=Tbase+dT(t)×Tmax, where Tbase is a base time window value; Tmax is the maximum allowable time window adjustment.

The fuzzy variables of the inputs and outputs are expressed by the following linguistic variables: “positive big (PB)”, “positive medium (PM)”, “positive small (PS)”,“Zero (ZO)”, “negative big (NB)”, “negative medium (NM)”, “negative small (NS)”.

The fuzzy-logic rules to determine the output (dT) based on the input values are listed in TABLE I below.

TABLE I
RULES FOR TIME WINDOW ADJUSTMENT IN LPF

| | |
|---|---|
| Input | Output |

| dP | SoC | dT |
|---|---|---|
| PB | ZO | PB |
| PM | ZO | PM |
| PS | ZO | PS |
| PB | NB or PB | PS |
| PS~PM | NB or PB | ZO |

The parameters in the fuzzy-logic based power controller 710 are generally designed based on human expertise or prior knowledge of the system operation, and can be tuned through, e.g., system simulation studies.

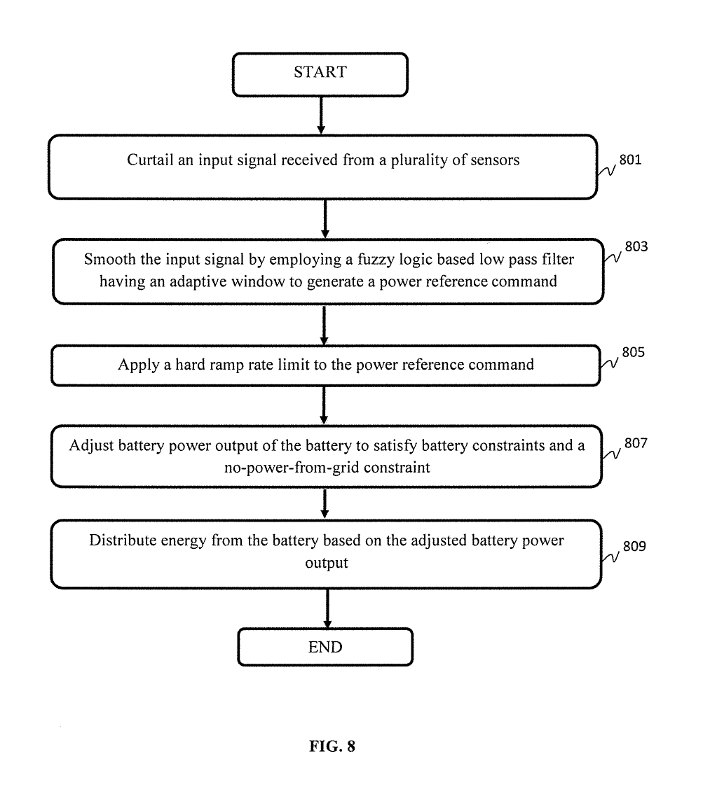

FIG. 8 is block/flow diagram illustrating a method for achieving a smooth PV output profile, in accordance with embodiments of the present invention.

At block 801, curtail an input signal received from a plurality of sensors.

At block 803, smooth the input signal by employing a fuzzy logic based low pass filter having an adaptive window to generate a power reference command.

At block 805, apply a hard ramp rate limit to the power reference command.

At block 807, adjust battery power output of the battery to satisfy battery constraints and a no-power-from-grid constraint.

At block 809, distribute energy from the battery based on the adjusted battery power output.

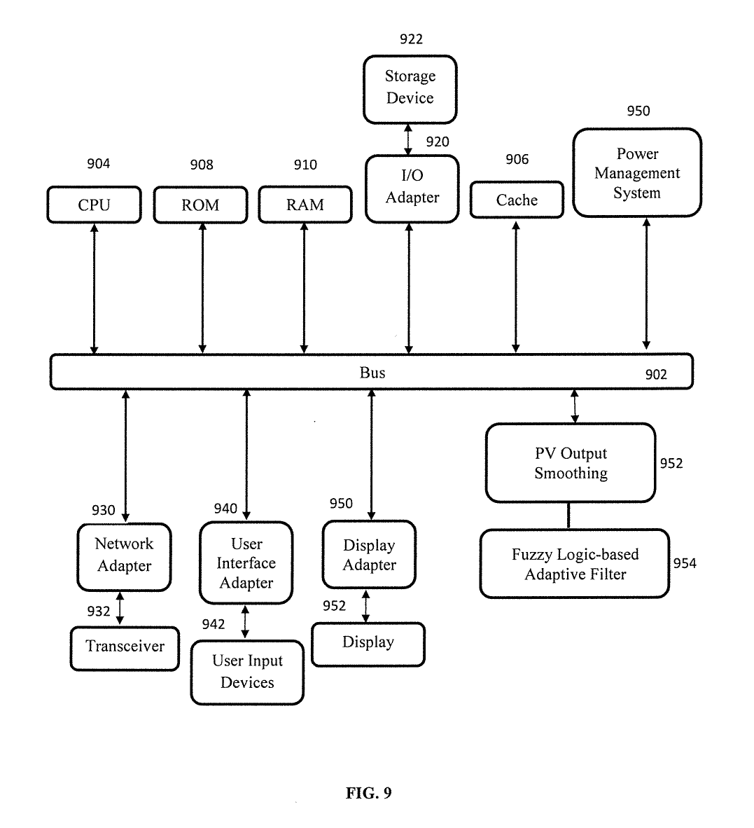

FIG. 9 is a block/flow diagram of an exemplary processing system, in accordance with embodiments of the present invention.

The processing system includes at least one processor (CPU) 904 operatively coupled to other components via a system bus 902. A cache 906, a Read Only Memory (ROM) 908, a Random Access Memory (RAM) 910, an input/output (I/O) adapter 920, a network adapter 930, a user interface adapter 940, and a display adapter 950, are operatively coupled to the system bus 902. Additionally, a power management system 950 is operatively coupled to the system bus 902. The power management system 950 can manipulate a fuzzy logic based low pass filter 954 to achieve PV output smoothing 952.

A storage device 922 is operatively coupled to system bus 902 by the I/O adapter 920. The storage device 922 can be any of a disk storage device (e.g., a magnetic or optical disk storage device), a solid state magnetic device, and so forth.

A transceiver 932 is operatively coupled to system bus 902 by network adapter 930.

User input devices 942 are operatively coupled to system bus 902 by user interface adapter 940. The user input devices 942 can be any of a keyboard, a mouse, a keypad, an image capture device, a motion sensing device, a microphone, a device incorporating the functionality of at least two of the preceding devices, and so forth. Of course, other types of input devices can also be used, while maintaining the spirit of the present invention. The user input devices 942 can be the same type of user input device or different types of user input devices. The user input devices 942 are used to input and output information to and from the processing system.

A display device 952 is operatively coupled to system bus 902 by display adapter 950.

Of course, the deep neural network processing system may also include other elements (not shown), as readily contemplated by one of skill in the art, as well as omit certain elements. For example, various other input devices and/or output devices can be included in the system, depending upon the particular implementation of the same, as readily understood by one of ordinary skill in the art. For example, various types of wireless and/or wired input and/or output devices can be used. Moreover, additional processors, controllers, memories, and so forth, in various configurations can also be utilized as readily appreciated by one of ordinary skill in the art. These and other variations of the deep neural network processing system are readily contemplated by one of ordinary skill in the art given the teachings of the present invention provided herein.

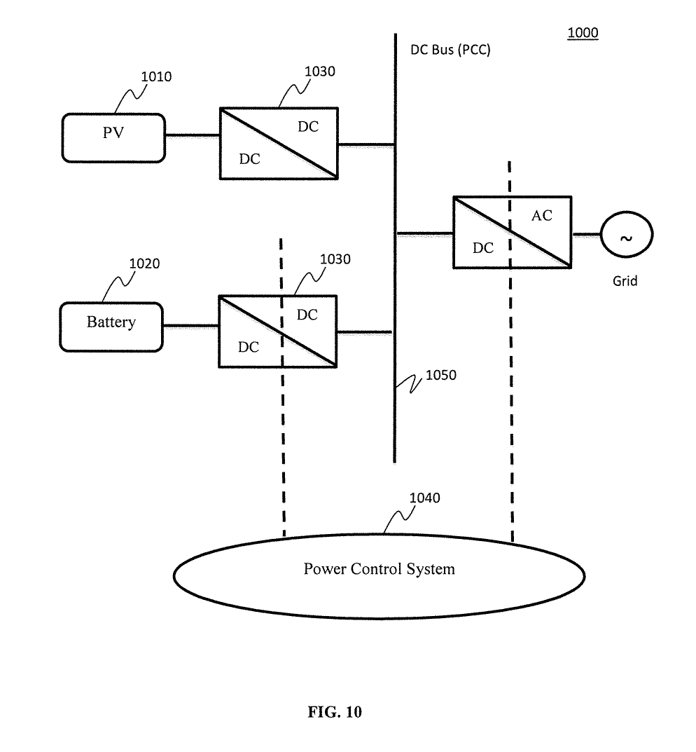

FIG. 10 is a system configuration 1000 of PV generation integrated with a battery, in accordance with embodiments of the present invention.

The battery 1020 is integrated with a PV device 1010 through bidirectional DC-DC converters (MPPT) 1030. The battery 1020 changes/discharges in corresponding to the power reference command from the power control system 1040. The system power output is the summation of battery power and PV power generation at the common coupling point (PCC) 1050.

The power control system 1040 receives PV production and battery status information in real-time during each time period and calculates the power reference for the battery 1020 to follow in the next time period. The calculation is based on the system constraints, such as battery energy/power capacity limits, battery state of charge (SoC) allowance, grid constraints and ramp rate limits, given in the following mathematical forms:

|Pout(t)−Pout(t−1)|≤Rmax (1);

Pdismax≤−Pbe(t)≤Pchmax (2);

SoC min≤SoC(t)≤SoC max (3);

Pbe(t)≤Ppv(t) (4);

where Pout (t) is the power output at time t; Rmax is the ramp rate limit. Pbe(t) is the battery discharging power (if positive) or charging power (if negative) at time t; Pchmax is the value of the max battery charging power; Pdismax is the value of the max battery discharging power.

SoC(t) is the SoC of the battery at time t; SoC min is the minimum allowed battery SoC and SoCmax is the maximum allowed battery SoC. Ppv(t) is the original PV power generation at time t.

Eqn. (1) guarantees the ramp rate constraints are satisfied. Eqn. (2) and (3) ensure the battery power and SoC are within their limits. Eqn. (4) ensures the battery only charges from the PV not from the grid.

The exemplary embodiments of the present invention help energy storage owners to bet storage systems (ESS) to achieve a smoother PV output profile that can satisfy all ramp rate and curtailment requirements.

The exemplary embodiments of the present invention can include all or some of the following:

Adaptive to the variation in PV power generation and battery operation conditions. Achieve a smooth PV profile also limit the battery capacity usage and battery throughput. Thus, the methods help to reduce cost on battery installation and operation.

Provide an instant, real-time control system. Does not need complex mathematical modeling or sophisticated prediction, and mainly relies on on-line system measurement.

Easy for updating when different types of energy storage devices are employed with different component configurations different unit size, different operation constraints, etc.) are applied.

Conserve battery life of the ESS by not violating the operational limits.

Effective in achieving any targeted PV profile given ESS with sufficient energy and power ratings, etc.

Therefore, the exemplary embodiments of the present invention introduce a fuzzy logic based power management system for PV output control where there is no need for complicated component modeling, effective PV power output performance can be obtained, and safe and sustainable operation can be achieved for different energy storage elements. Consequently, an adaptive control system for battery integrated PV generation is designed to reduce the fluctuations in PV power production. The core component of the system is a four-layer power control system (PCS) for Battery Energy Storage (BES). BES responds to the power dispatch commands from PCS and charges/discharges to mitigate variations in PV power output. As a core part of the system, a PV power smoothing algorithm is introduced to reduce battery capacity requirements and save battery life loss by adaptively adjusting control parameter settings based on system real-time characteristics.

The adaptive and integrated PV power control system can be equipped with BES and can be designed to mitigate the impact of short-term variations of PV generation to provide the grid with smoother PV profile, while also reduce the battery cycle life loss by dynamically adjusting the parameters of the smoothing algorithm based on real-time system inputs. The exemplary embodiments of the present invention are general enough to be applied to any PV generation profile and achieve any target PV output profile with predetermined ramp rate limits. The exemplary embodiments of the present invention also provide guidelines to choose optimal battery size to reduce cost on infrastructure and operation.

As will be appreciated by one skilled in the art, aspects of the present invention may be embodied as a system, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical data storage device, a magnetic data storage device, or any suitable combination of the foregoing. In the context of this document, a computer readable storage medium may be any tangible medium that can include, or store a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present invention may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present invention are described below with reference to flowchart illustrations and/or block diagrams of methods, apparatus (systems) and computer program products according to embodiments of the present invention. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks or modules.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks or modules.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks or modules.

It is to be appreciated that the term “processor” as used herein is intended to include any processing device, such as, for example, one that includes a CPU (central processing unit) and/or other processing circuitry. It is also to be understood that the term “processor” may refer to more than one processing device and that various elements associated with a processing device may be shared by other processing devices.

The term “memory” as used herein is intended to include memory associated with a processor or CPU, such as, for example, RAM, ROM, a fixed memory device (e.g., hard drive), a removable memory device (e.g., diskette), flash memory, etc. Such memory may be considered a computer readable storage medium.

In addition, the phrase “input/output devices” or “I/O devices” as used herein is intended to include, for example, one or more input devices (e.g., keyboard, mouse, scanner, etc.) for entering data to the processing unit, and/or one or more output devices (e.g., speaker, display, printer, etc.) for presenting results associated with the processing unit.

The foregoing is to be understood as being in every respect illustrative and exemplary, but not restrictive, and the scope of the invention disclosed herein is not to be determined from the Detailed Description, but rather from the claims as interpreted according to the full breadth permitted by the patent laws. It is to be understood that the embodiments shown and described herein are only illustrative of the principles of the present invention and that those skilled in the art may implement various modifications without departing from the scope and spirit of the invention. Those skilled in the art could implement various other feature combinations without departing from the scope and spirit of the invention. Having thus described aspects of the invention, with the details and particularity required by the patent laws, what is claimed and desired protected by Letters Patent is set forth in the appended claims.

What is claimed is:

1. A computer-implemented method executed on a processor for outputting a smoothed photovoltaic (PV) power output from a battery of a power control system communicating with one or more microgrids, the method comprising:
curtailing an input signal received from a plurality of sensors;
smoothing the input signal by employing a fuzzy logic based low pass filter having an adaptive window to generate a power reference command;
applying a hard ramp rate limit to the power reference command;
adjusting battery power output of the battery to satisfy battery constraints and a no-power-from-grid constraint; and
distributing energy from the battery based on the adjusted battery power output.

2. The method of claim 1, wherein the input signal is a raw PV generation profile.

3. The method of claim 1, wherein battery constraints include at least a battery state of charge (SOC) constraint and a battery power limit constraint.

4. The method of claim 1, wherein a filter time of the fuzzy logic based low pass filter is adjusted based on at least one of input PV variation and battery status.

5. The method of claim 1, further comprising limiting curtailment and ramp rate control when the battery is approaching a state of charge (SOC) limit.

6. The method of claim 1, further comprising employing an iterative process to obtain minimal battery size by assuming a large battery size and reducing the battery size by a step value each iteration until a PV curtailment limit is violated.

7. The method of claim 1, wherein the fuzzy logic based low pass filter adjusts a low pass filter time window, in real-time, based on a variation in PV power production and a state of charge (SOC) of the battery.

8. A system for outputting a smoothed photovoltaic (PV) power output from a battery of a power control system communicating with one or more microgrids, the system comprising:
a memory; and
a processor in communication with the memory, wherein the processor runs program code to:
curtail an input signal received from a plurality of sensors;
smooth the input signal by employing a fuzzy logic based low pass filter having an adaptive window to generate a power reference;
apply a hard ramp rate limit to the power reference;
adjust battery power output of the battery to satisfy battery constraints and a no-power-from-grid constraint; and
distribute energy from the battery based on the adjusted battery power output.

9. The system of claim 8, wherein the input signal is a raw PV generation profile.

10. The system of claim 8, wherein battery constraints include at least a battery state of charge (SOC) constraint and a battery power limit constraint.

11. The system of claim 8, wherein a filter time of the fuzzy logic based low pass filter is adjusted based on at least one of input PV variation and battery status.

12. The system of claim 8, wherein curtailment and ramp rate control are limited when the battery is approaching a state of charge (SOC) limit.

13. The system of claim 8, wherein an iterative process is employed to obtain minimal battery size by assuming a large battery size and reducing the battery size by a step value each iteration until a PV curtailment limit is violated.

14. The system of claim 8, wherein the fuzzy logic based low pass filter adjusts a low pass filter time window, in real-time, based on a variation in PV power production and a state of charge (SOC) of the battery.

15. A non-transitory computer-readable storage medium comprising a computer-readable program for outputting a smoothed photovoltaic (PV) power output from a battery of a power control system communicating with one or more microgrids, wherein the computer-readable program when executed on a computer causes the computer to perform the steps of:
curtailing an input signal received from a plurality of sensors;
smoothing the input signal by employing a fuzzy logic based low pass filter having an adaptive window to generate a power reference command;
applying a hard ramp rate limit to the power reference command;
adjusting battery power output of the battery to satisfy battery constraints and a no-power-from-grid constraint; and
distributing energy from the battery based on the adjusted battery power output.

16. The non-transitory computer-readable storage medium of claim 15, wherein battery constraints include at least a battery state of charge (SOC) constraint and a battery power limit constraint.

17. The non-transitory computer-readable storage medium of claim 15, wherein a filter time of the fuzzy logic based low pass filter is adjusted based on at least one of input PV variation and battery status.

18. The non-transitory computer-readable storage medium of claim 15, wherein curtailment and ramp rate control are limited when the battery is approaching a state of charge (SOC) limit.

19. The non-transitory computer-readable storage medium of claim 15, wherein an iterative process is employed to obtain minimal battery size by assuming a large battery size and reducing the battery size by a step value each iteration until a PV curtailment limit is violated.

20. The non-transitory computer-readable storage medium of claim 15, wherein the fuzzy logic based low pass filter adjusts a low pass filter time window, in real-time, based on a variation in PV power production and a state of charge (SOC) of the battery.
